(19) United States
(12) Patent Application Publication
(10) Pub. No.: US 2014/0209143 A1
(43) Pub. Date: Jul. 31, 2014

(54) PHOTOVOLTAIC ASSEMBLY WITH CLEANING MEMBER

(71) Applicant: Hon Hai Precision Industry Co., Ltd., New Taipei (TW)

(72) Inventors: YU-CHEN TING, New Taipei (TW); CHIH-HANG CHAO, New Taipei (TW)

(73) Assignee: HON HAI PRECISION INDUSTRY CO., LTD., New Taipei (TW)

(21) Appl. No.: 14/027,158

(22) Filed: Sep. 14, 2013

(30) Foreign Application Priority Data
Jan. 28, 2013 (TW) 102103227

(51) Int. Cl. H01L 31/042

(52) U.S. Cl. CPC H01L 31/042
USPC 136/244

(57) ABSTRACT

A photovoltaic assembly includes a solar plate, a first driving device, and a first cleaning member secured to the first driving device. The solar plate includes a front surface, a first side edge and a second side edge connected to the first side edge. The first cleaning member includes a bottom surface, and is rotatable by the first driving device. The bottom surface contacts with the front surface and is slidable relative to the solar plate between a first position and a second position. In the first position, the bottom surface is aligned with the first side edge. In the second position, the bottom surface is aligned with the second side edge.

### BACKGROUND

1. Technical Field

The present disclosure relates to photovoltaic assemblies, and more particularly to a photovoltaic assembly having a cleaning member.

2. Description of Related Art

A photovoltaic device is often used to change the solar energy to electric energy. The photovoltaic device comprises a solar plate for receiving sunlight. However, coverings, such as snow or dust, may pile on and shield the solar plate after long time outdoor use then the solar plate cannot receive sunlight. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like-reference numerals designate corresponding parts throughout the several views.

FIG. 1 is an exploded, isometric view of a photovoltaic assembly in accordance with an embodiment.

FIG. 2 is an enlarged view of a circled portion II of FIG. 1.

FIG. 3 is an assembled view of the photovoltaic assembly of FIG. 1, wherein a cleaning member is in a first position.

FIG. 4 is similar to FIG. 3, but viewed from a different aspect.

FIG. 5 is a top view of the photovoltaic assembly of FIG. 3.

FIG. 6 is similar to FIG. 5, wherein the cleaning member is rotated.

FIG. 7 is similar to FIG. 5, wherein the cleaning member is in a second position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

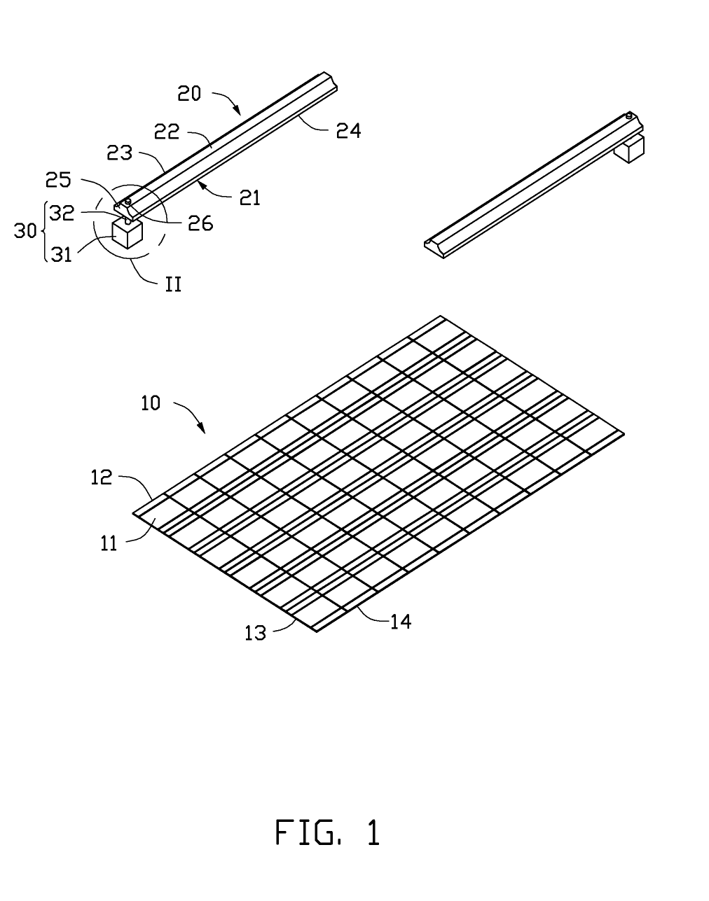

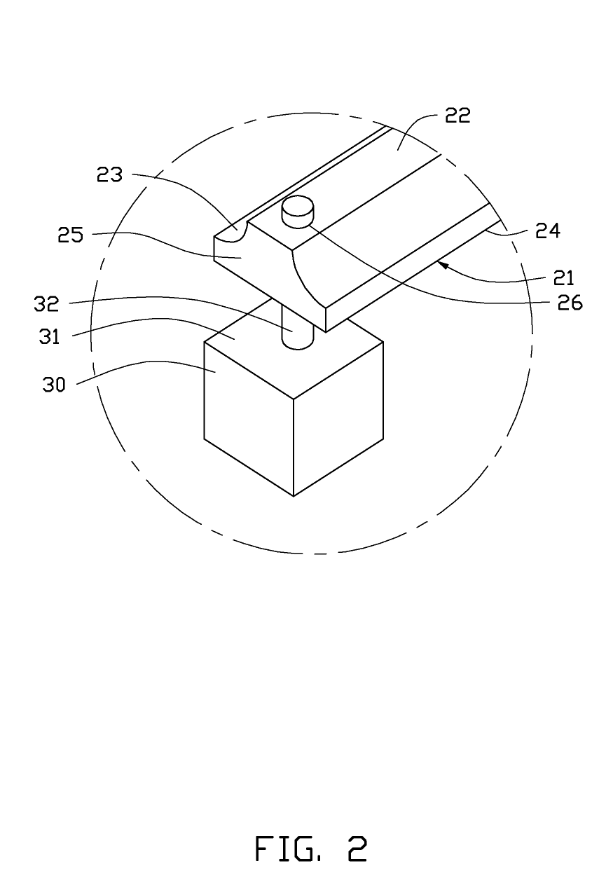

FIGS. 1-2 illustrate a photovoltaic assembly in accordance with an embodiment. The photovoltaic assembly comprises a solar plate 10, two cleaning members 20, and two driving devices 30.

The solar plate 10 comprises a front surface 11, a rear surface 12, a first side edge 13, and a second side edge 14 connected to the first side edge 13. In one embodiment, the first side edge 13 is substantially perpendicular to the second side edge 14, and a length of the first side edge 13 is less than a length of the second side edge 14. The solar plate 10 is substantially a rectangle.

Each cleaning member 20 comprises a bottom surface 21, a top surface 22, two first side surfaces 24, two second side surfaces 25, and two receiving surfaces 23. In one embodiment, the top surface 22 is substantially parallel to the bottom surface 21. Each first side surface is substantially perpendicular to the bottom surface 21 and connected to each receiving surface 23, and each receiving surface is substantially arc-shaped. Each second side surface 25 is substantially connected to the bottom surface 21 and the top surface 22. In one embodiment, a length of the bottom surface 21 is substantially equal to the length of the first side edge 13. A through hole 26 is defined in an end of the cleaning member 20.

Each driving device 30 comprises a driving member 31 and a rotating shaft 32 connected to the driving member 31. The driving member 31 is used to rotate the rotating shaft 32, to rotate the cleaning member 20 about the rotating shaft 32. When the cleaning member 20 has been rotated, the bottom surface 21 contacts with the front surface 11 to clean away the coverings from the front surface 11. In one embodiment, the driving member 31 is a motor.

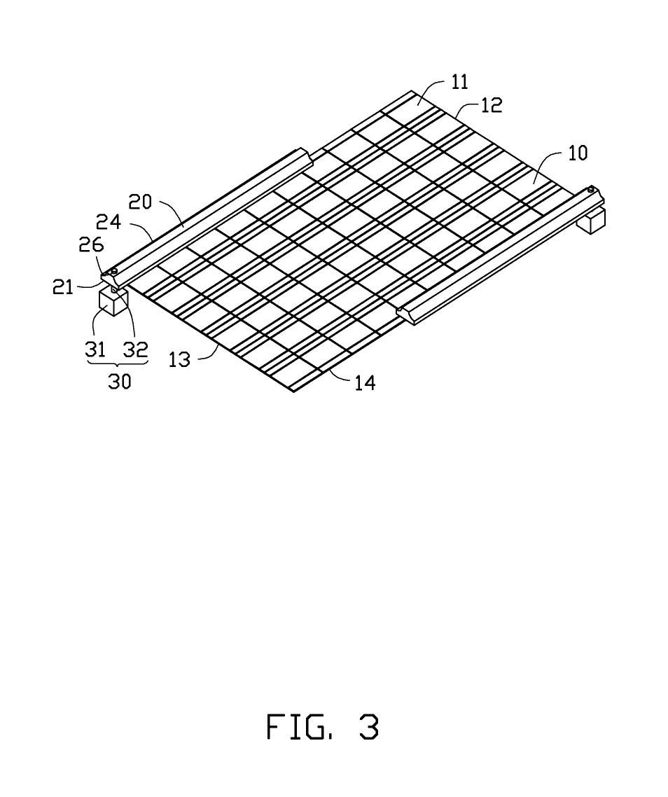

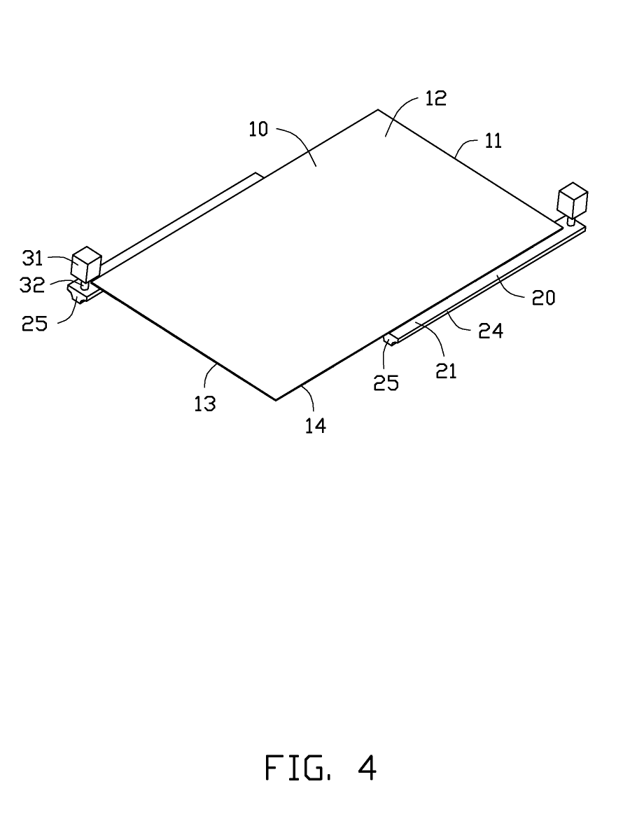

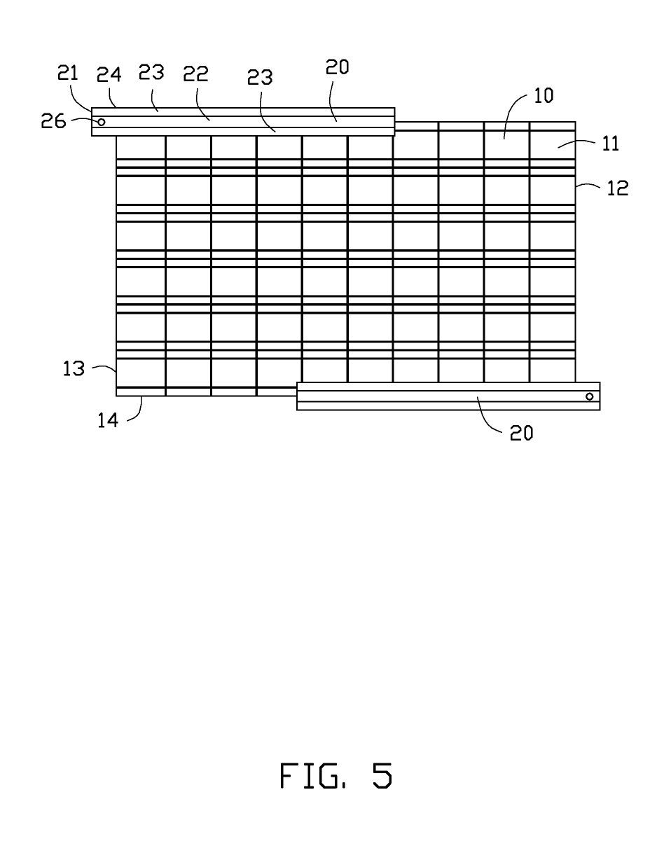

FIGS. 3-5 illustrate that in assembly, each rotating shaft 32 extends through each through hole 26, to secure each driving device 30 to each cleaning member 20. A first one of the two driving devices 30 is located on a first corner of the solar plate 10, and the cleaning member 20, being secured to the first one of the two driving devices 30, is aligned with a first one of the two second side edges 14. A second one of the two driving devices 30 is located on a second corner of the solar plate 10, and the cleaning member 20, being secured to the second one of the two driving devices 30, is aligned with a second one of the two second side edges 14. In one embodiment, a connecting line connecting the first corner and the second corner is a diagonal line of the rectangle defined by the solar plate 10. At this time, the cleaning member 20 is located on a first position (see FIG. 3).

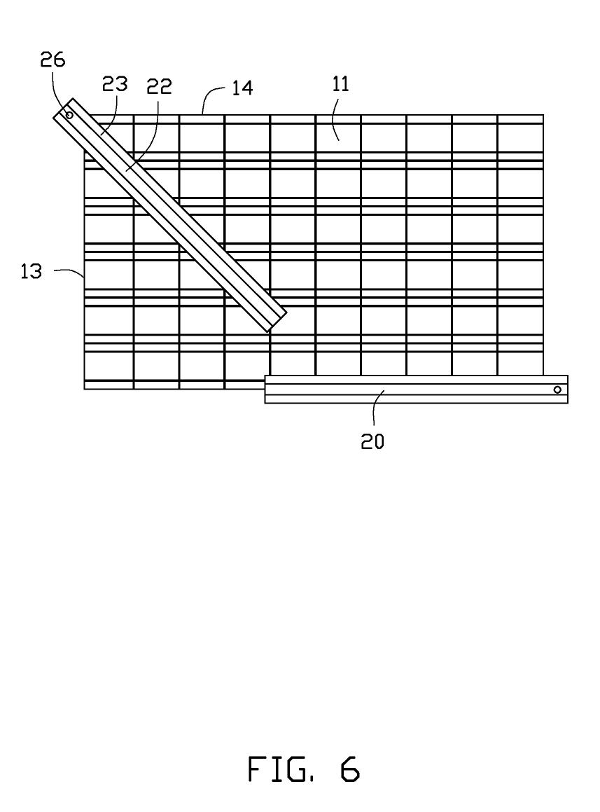

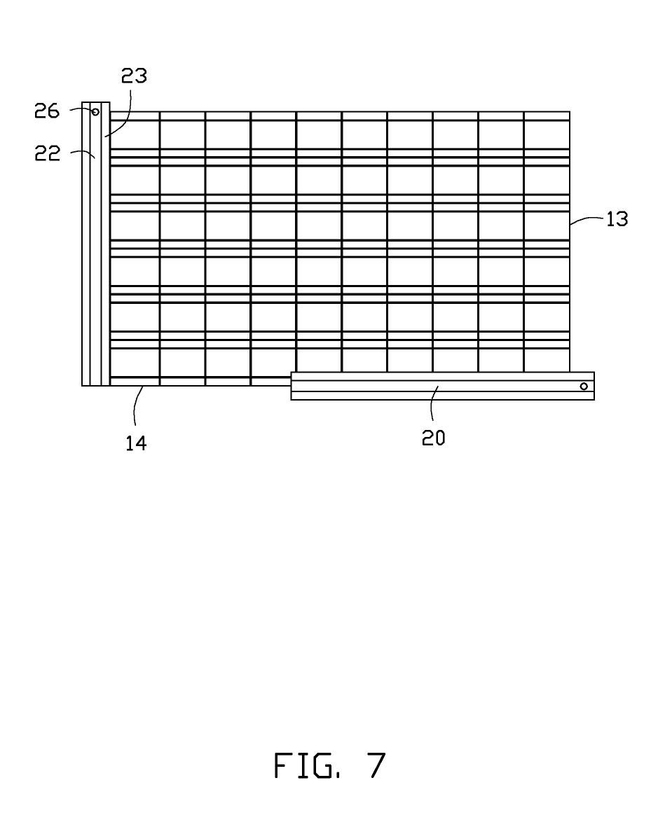

FIGS. 6-7 illustrate that in use, the first one of the two driving devices 30 works to rotate the rotating shaft 32 in a first direction, rotating the first one of the cleaning members 20 about the rotating shaft 32 (see FIG. 7). When the cleaning member 20 is rotated, the bottom surface 21 contacts with the front surface 11 and is slid on the bottom surface 21. Thus, the coverings on the bottom surface 21 can be cleaned by the bottom surface 21 and received in the receiving surface 23. Until the cleaning member 20 is rotatably aligned with the a first one of the two first side edges 13 and located on a second position (see FIG. 6), the first one of the two driving devices 30 works to rotate the rotating shaft 32 in a second direction opposite to the first direction. In addition, the first one of the cleaning members 20 is rotated about the rotating shaft 32 back to the first position. Thus, the solar plate 10 is cleaned again.

After the solar plate 10 is cleaned by the first one of the cleaning members 20, the first one of the two driving devices 30 stops working, and the second one of the two driving devices 30 works. Thus, as the first one of the two cleaning members 20, the solar plate 10 is cleaned again by the second one of the two cleaning members 20.

In one embodiment, the two driving members 31 can work simultaneously, and solar plate 10 can be simultaneously cleaned by the two cleaning members 20. The lengths of the two cleaning members 20 are suitable that the two cleaning members 20 cannot make contact with each other.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A photovoltaic assembly comprising:
a solar plate comprising a front surface;
a first driving device; and
a first cleaning member, secured to the first driving device, comprising a bottom surface, a top surface, and a receiving surface located between the bottom surface and the top surface;
wherein the first cleaning member is rotatable by the first driving device, and the bottom surface contacts the front surface and is slidable relative to the solar plate, to clean away a covering from the receiving surface.

2. The photovoltaic assembly of claim 1, wherein the receiving surface is substantially arc-shaped.

3. The photovoltaic assembly of claim 1, wherein the solar plate comprises a first side edge and a second side edge connected to the first side edge; the first cleaning member is rotatable relative to the solar plate between a first position, where the bottom surface is aligned with the first side edge, and a second position, where the bottom surface is aligned with the second side edge.

4. The photovoltaic assembly of claim 3, further comprising a second driving device and a second cleaning member secured to the second driving device; wherein when the first cleaning member is located in the first position, the second cleaning member is substantially parallel to the first cleaning member; and when the first cleaning member is located in the second position, the second cleaning member is substantially perpendicular to the first cleaning member.

5. The photovoltaic assembly of claim 3, wherein the first side edge is substantially perpendicular to the second side edge.

6. The photovoltaic assembly of claim 3, wherein a length of the first side edge is less than a length of the second side edge.

7. The photovoltaic assembly of claim 1, wherein the first cleaning member further comprises a first side surface substantially perpendicular to the bottom surface, and the receiving surface is connected to the first side surface and the top surface.

8. The photovoltaic assembly of claim 1, wherein the top surface is substantially parallel to the bottom surface.

9. The photovoltaic assembly of claim 1, wherein the first driving device comprises a driving member and a rotating shaft connected to the driving member, and the rotating shaft is secured to the first cleaning member.

10. A photovoltaic assembly comprising:
a solar plate comprising a front surface, a first side edge and a second side edge connected to the first side edge;
a first driving device; and
a first cleaning member, secured to the first driving device, comprising a bottom surface;
wherein the first cleaning member is rotatable by the first driving device, and the bottom surface contacts the front surface and slidable relative to the solar plate between a first position and a second position; in the first position, the bottom surface is aligned with the first side edge; and in the second position, the bottom surface is aligned with the second side edge.

11. The photovoltaic assembly of claim 10, wherein the first cleaning member further comprises a top surface and a receiving surface located between the bottom surface and the top surface, and the receiving surface is configured to receive coverings by the first cleaning member.

12. The photovoltaic assembly of claim 11, wherein the receiving surface is substantially arc-shaped.

13. The photovoltaic assembly of claim 11, wherein the top surface is substantially parallel to the bottom surface.

14. The photovoltaic assembly of claim 11, wherein the first cleaning member further comprises a first side surface that is perpendicular to the bottom surface, and the receiving surface is connected to the first side surface and the top surface.

15. The photovoltaic assembly of claim 10, further comprising a second driving device and a second cleaning member secured to the second driving device; wherein when the first cleaning member is located in the first position, the second cleaning member is substantially parallel to the first cleaning member; and when the first cleaning member is located in the second position, the second cleaning member is substantially perpendicular to the first cleaning member.

16. The photovoltaic assembly of claim 10, wherein the first side edge is substantially perpendicular to the second side edge.

17. The photovoltaic assembly of claim 10, wherein a length of the first side edge is less than a length of the second side edge.

18. The photovoltaic assembly of claim 10, wherein the first driving device comprises a driving member and a rotating shaft connected to the driving member, and the rotating shaft is secured to the first cleaning member.
